(19) United States
(12) Patent Application Publication
(10) Pub. No.: US 2016/0322411 A1
(43) Pub. Date: Nov. 3, 2016

(54) RADIOGRAPHY FLAT PANEL DETECTOR HAVING A LOW WEIGHT X-RAY SHIELD AND THE METHOD OF PRODUCTION THEREOF

(71) Applicant: AGFA HEALTHCARE, B- Mortsel (BE)

(72) Inventors: Sabina ELEN, Mortsel (BE); Luc STRUYE, Mortsel (BE); Dirk VANDENBROUCKE, Mortsel (BE); Jean-Pierre TAHON, Mortsel (BE)

(21) Appl. No.: 15/102,627

(22) PCT Filed: Dec. 12, 2014
(86) PCT No.: PCT/EP2014/077613

§ 371 Date: Jun. 8, 2016

(30) Foreign Application Priority Data
Dec. 17, 2013 (EP) 13197736.5

(51) Int. Cl. H01L 27/146; G01T 1/20

(52) U.S. Cl. CPC H01L 27/14623; G01T 1/2018; H01L 27/14663; H01L 27/14689; H01L 27/14685

(57) ABSTRACT

A radiography flat panel detector and a method of producing the flat panel detector including, in a scintillating or photoconductive layer, an imaging array, -a substrate, and an X-ray absorbing layer including a chemical compound having a metal element with an atomic number of 20 or more and one or more non-metal elements. The X-ray absorbing layer has a dimensionless absorption exponent of greater than 0.5 for gamma ray emission of Am²⁴¹ at about 60 keV, wherein

AE(Am²⁴¹ 60 keV)=t*(k₁e₁+k₂e₂+k₃e₃+ . . . )

and AE(Am²⁴¹ 60 keV) represents the absorption exponent of the X-ray absorbing layer relative to the about 60 keV gamma ray emission of Am²⁴¹; t represents the a thickness of the X-ray absorbing layer; e₁, e₂, e₃, . . . represent concentrations of the elements in the X-ray absorbing layer; and k₁,k₂,k₃ . . . represent mass attenuation coefficients of the elements. If the chemical compound is a scintillating phosphor, a layer is present between the X-ray absorbing layer and the substrate and has a transmission for light of 10% or lower at the wavelength of the light emission of the chemical compound.

### CROSS-REFERENCE TO RELATED APPLICATIONS

This application is a 371 National Stage Application of PCT/EP2014/077613, filed Dec. 12, 2014. This application claims the benefit of European Application No. 13197736.5, filed Dec. 17, 2013, which is incorporated by reference herein in its entirety.

### BACKGROUND OF THE INVENTION

1. Field of the Invention

The present invention relates to diagnostic imaging and more particularly, to a radiography X-ray detector having an X-ray shield which protects the detector electronics and reduces or eliminates the impact of backscattered X-rays during the exposure of the subject to the X-ray source.

2. Description of the Related Art

X-ray imaging is a non-invasive technique to capture medical images of patients or animals as well as to inspect the contents of sealed containers, such as luggage, packages, and other parcels. To capture these images, an X-ray beam irradiates an object. The X-rays are then attenuated as they pass through the object. The degree of attenuation varies across the object as a result of variances in the internal composition and/or thickness of the object. The attenuated X-ray beam impinges upon an X-ray detector designed to convert the attenuated beam to a usable shadow image of the internal structure of the object.

Increasingly, radiography flat panel detectors (RFPDs) are being used to capture images of objects during inspection procedures or of body parts of patients to be analyzed. These detectors can convert the X-rays directly into electric charges (direct conversion direct radiography—DCDR), or in an indirect way (indirect conversion direct radiography—ICDR).

In direct conversion direct radiography, the RFPDs convert X-rays directly into electric charges. The X-rays are directly interacting with a photoconductive layer such as amorphous selenium (a-Se).

In indirect conversion direct radiography, the RFPDs have a scintillating phosphor such as CsI:Tl caesium iodide doped with thallium) or Gd₂O₂S (gadolinium oxysulphide) which converts X-rays into light which then interacts with an amorphous silicon (a-Si) semiconductor layer, where electric charges are created.

The created electric charges are collected via a switching array, comprising thin film transistors (TFTs). The transistors are switched-on row by row and column by column to read out the signal of the detector. The charges are transformed into voltage, which is converted in a digital number that is stored in a computer file which can be used to generate a softcopy or hardcopy image. Recently Complementary Metal Oxides Semiconductors (CMOS) sensors are becoming important in X-ray imaging. The detectors based on CMOS are already used in mammography, dental, fluoroscopy, cardiology and angiography images. The advantage of using those detectors is a high readout speed and a low electronic noise.

Generally, the imaging array including TFTs as switching array and photodiodes (in case of ICDR) is deposited on a thin substrate of glass. The assembly of scintillator or photoconductor and the imaging array on the glass substrate does not absorb all primary radiation, coming from the X-ray source and transmitted by the object of the diagnosis. Hence the electronics positioned under this assembly are exposed to a certain fraction of the primary X-ray radiation. Since the electronics are not sufficiently radiation hard, this transmitted radiation may cause damage.

Moreover, X-rays which are not absorbed by the assembly of scintillator or photoconductor and the imaging array on the glass substrate, can be absorbed in the structures underneath the glass substrate. The primary radiation absorbed in these structures generates secondary radiation that is emitted isotropically and that thus exposes the imaging part of the detector. The secondary radiation is called “backscatter” and can expose the image part of the detector thereby introducing artefacts into the reconstructed image. Since the space under the assembly is not homogeneously filled, the amount of scattered radiation is position dependent. Part of the scattered radiation is emitted in the direction of the assembly of scintillator or photoconductor and imaging array and may contribute to the recorded signal. Since this contribution is not spatially homogeneous this contribution will lead to haze in the image, and, therefore, reduce the dynamic range. It will also create image artefacts.

To avoid damage to the electronics and image artefacts due to scattered radiation, an X-ray shield may be applied underneath the assembly of scintillator or photoconductor and imaging array. Because of their high density and high intrinsic stopping power for X-rays, metals with a high atomic number are used as materials in such an X-ray shield. Examples of these are sheets or plates from tantalum, lead or tungsten as disclosed in EP1471384B1, US2013/0032724A1, US2012/0097857A1.

However, metals with a high atomic number also have a high density. Hence, X-ray shields based on these materials have a high weight. Weight is an important characteristic of the RFPD especially for the portability of the RFPDs. Any weight reduction is, therefore, beneficial for the users of the RFPDs such as medical staff.

U.S. Pat. No. 7,317,190B2 discloses a radiation absorbing X-ray detector panel support comprising a radiation absorbing material to reduce the reflection of X-rays of the back cover of the X-ray detector. The absorbing material including heavy atoms such as lead, barium sulphate and tungsten can be disposed as a film via a chemical vapour deposition technique onto a rigid panel support or can be mixed via injection moulding with the base materials used to fabricate the rigid panel support. The support for the chemical vapour deposition as well as the base materials to fabricate the rigid panel support, represent an extra weight contribution in the RFPD. Moreover, the detector panel support comprising the radiation absorbing material needs to be additionally fixed to assure immobilisation to the detector.

In U.S. Pat. No. 5,650,626, an X-ray imaging detector is disclosed which contains a substrate, supporting the conversion and detection unit. The substrate includes one or more elements having atomic numbers greater than 22. Since the detection array is directly deposited on the substrate, the variety of suitable materials of the substrate is rather limited.

In U.S. Pat. No. 5,777,335, an imaging device is disclosed comprising a substrate, preferably glass containing a metal selected from a group formed by Pb, Ba, Ta or W. According to the inventors, the use of this glass would not require an additional X-ray shield based on lead. However, glass containing sufficient amounts of metals from a group formed by Pb, Ba, Ta or W is more expensive than glass which is normally used as a substrate for imaging arrays.

U.S. Pat. No. 7,569,832 discloses a radiographic imaging device, namely a RFPD, comprising two scintillating phosphor layers as scintillators each one having different thicknesses and a transparent substrate to the X-rays between said two layers. The use of an additional phosphor layer at the opposite side of the substrate improves the X-ray absorption while maintaining the spatial resolution. The presence of the additional phosphor layer as disclosed is not sufficient to absorb all primary X-ray radiation to prevent damage of the underlying electronics and to prevent backscatter. An extra X-ray shield will still be required in the design of this RFPD.

In US2008/011960A1 a dual-screen digital radiography apparatus is claimed. This apparatus consists of two flat panel detectors (front panel and back panel) each comprising a scintillating phosphor layer to capture and process X-rays. The scintillating phosphor layer in the back panel contributes to the image formation and has no function as X-ray shield to protect the underlying electronics. This dual-screen digital flat panel, still requires an X-ray shield to protect the underlying electronics and to avoid image artefacts due to scattered radiation.

WO20051055938 discloses a light weight film, with an X-ray absorption at least equivalent to 0.254 mm of lead and which has to be applied on garments or fabrics for personal radiation protection or attenuation, such as aprons, thyroid shields, gonad shields, gloves, etc. Said film is obtained from a polymer latex mixture comprising high atomic weight metals or their related compounds and/or alloys. The suitable metals are the ones that have an atomic number greater than 45. No use of this light weight film in a RFPD is mentioned. Although a light weight film is claimed, the metal particles used in the composition of the film still contribute to a high extend to the weight of the shield.

U.S. Pat. No. 6,548,570 discloses a radiation shielding composition to be applied on garments or fabrics for personal radiation protection. The composition comprised a polymer, preferably an elastomer, and a homogeneously dispersed powder of a metal with high atomic number in an amount of at least 80% in weight of the composition as filler. A loading material is mixed with the filler material and kneaded with the elastomer at a temperature below 180° C. resulting in a radiation shielding composition that can be applied homogeneously to garments and fabrics on an industrial scale. The use of metals is however increasing the weight of the shield of this invention considerably.

WO2009/0078891 discloses a radiation shielding sheet which is free from lead and other harmful components having a highly radiation shielding performance and an excellent economical efficiency. Said sheet is formed by filling a shielding material into an organic polymer material, the shielding material being an oxide powder containing at least one element selected from the group consisting of lanthanum (La), cerium (Ce), praseodymium (Pr), neodymium (Nd), samarium (Sm), europium (Eu) and gadolinium (Gd) and the polymer being a material such as rubber, thermoplastic elastomer, polymer resin or similar. The volumetric amount of the shielding material filled in the radiation shielding sheet is 40 to 80 vol. % with respect to the total volume of the sheet. No use of this film into a RFPD is mentioned.

From the foregoing discussion, it should be apparent that there is a need for a RFPD with an X-ray shield to protect the underlying electronics and to absorb the scattered radiation produced by the underlying structures to avoid image artefacts in the imaging area, but which has a low weight, a low cost, which can be produced in an economically efficient way and which does not have to be fixed to the substrate of the imaging array in an additional step of the production.

### SUMMARY OF THE INVENTION

It is therefore an object of the present invention to provide a solution for the high weight contribution of the X-ray shield in a radiography flat panel detector having a single imaging array and to provide at the same time a solution for producing the RFPD on an economically efficient way. This object has been achieved by a radiography flat panel detector as defined below.

An additional advantage of the RFPD is that the thickness of said X-ray shield can be adjusted in a continuous way to the required degree of the X-ray shielding effect instead of in large steps as it is in the case of shielding metal sheets commercially available with standard thicknesses. Even though plates with custom made thickness can be purchased, the price of those metal plates is still very high because of the customization.

According to another aspect, the present invention includes a method of manufacturing a radiography flat panel detector. The method includes coating or depositing on the substrate of the imaging array, preferably on the opposite side of the imaging array, an X-ray absorbing layer with at least one chemical compound having a metal element with an atomic number of 20 or more and one or more non-metal elements and which has a dimensionless absorption exponent for 60 keV Am²⁴¹ source greater than 0.5 as defined in claim 1.

Other features, elements, steps, characteristics and advantages of the present invention will become more apparent from the following detailed description of preferred embodiments of the present invention. Specific preferred embodiments of the invention are also defined below.

### BRIEF DESCRIPTION OF THE DRAWINGS

FIG. 1 represents a cross-section of a RFPD according to one preferred embodiment of the present invention and the underlying electronics, wherein:

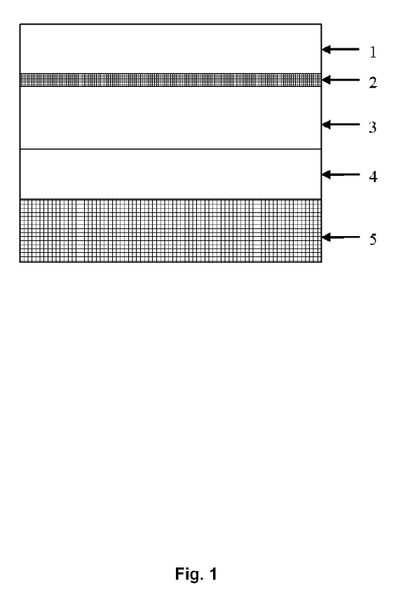

1 is a scintillator or photoconductive layer

2 is single imaging array

3 is a substrate

4 is an X-ray absorbing layer

5 is the underlying electronics

### DETAILED DESCRIPTION OF THE PREFERRED EMBODIMENTS

The present invention relates to a radiography flat panel detector (RFPD) comprising a scintillator or photoconductive layer, a single imaging array on a substrate and an X-ray shield having an X-ray absorbing layer comprising a chemical compound having a metal element with an atomic number of 20 or more and one or more non-metal elements coated or deposited on a side of a substrate of an imaging array. If the chemical compound in the X-ray absorbing layer is a scintillating phosphor, a layer is present between the X-ray absorbing layer and the substrate, which has a transmission for light of 10% or lower at the wavelength of the light emission of said chemical compound.

### The X-Ray Absorbing Layer

It has been found that X-ray shields can be made with the same X-ray stopping power but with considerably less weight than X-ray shields consisting of metals only by use of a layer comprising one or more chemical compounds having a metal element with an atomic number of 20 or more and one or more non-metal elements. Preferably these compounds are oxides or salts such as halides, oxysulphides, sulphites, carbonates of metals with an atomic number of 20 or higher. Examples of suitable metal elements with an atomic number higher than 20 that can be used in the scope of the present invention are metals such as Barium (Ba), Calcium (Ca), Cerium (Ce), Caesium (Cs), Gadolinium (Gd), Lanthanum (La), Lutetium (Lu), Palladium (Pd), Tin (Sn), Strontium (Sr), Tellurium (Te), Yttrium (Y), and Zinc (Zn). A further advantage of the invention is that these compounds are relatively inexpensive and are characterised by a low toxicity.

Examples of preferred compounds having a metal element with an atomic number of 20 or more and one or more non-metal elements, are Caesium iodide (CsI), Gadolinium oxysulphide (Gd₂O₂S), Barium fluorobromide (BaFBr), Calcium tungstate (CaWO₄), Barium titanate (BaTiO₃), Gadolinium oxide (Gd₂O₃), Barium chloride (BaCl₂), Barium fluoride (BaF₂), Barium oxide (BaO), Cerium oxides, Caesium nitrate (CsNO₃), Gadolinium fluoride (GdF₂), Palladium iodide (PdI₂), Tellurium dioxide (TeO₂), Tin iodides, Tin oxides, Barium sulphides, Barium carbonate (BaCO₃), Barium iodide, Caesium chloride (CsCl), Caesium bromide (CsBr), Caesium fluoride (CsF), Caesium sulphate (Cs₂SO₄), Osmium halides, Osmium oxides, Osmium sulphides, Rhenium halides, Rhenium oxides, Rhenium sulphides, BaFX (wherein X represents Cl or I), RFXₙ (wherein RF represents lanthanides selected from: La, Ce, Pr, Nd, Pm, Sm, Eu, Gd, Tb, Dy, Ho, Er, Tm, Yb, Lu and X represents halides selected from: F, Cl, Br, I), RF_{y}O_{z}, RF_{y}(SO₄)_{z}, RF_{y}S_{z} and/or RF_{y}(WO₄)_{z}, wherein n, y, z are independently an integer number higher than 1. These compounds can produce lower weight X-ray shields and are easy to handle due to their low hygroscopicity than their pure metal analogues. The most preferred metallic compounds are: Gd₂O₂S, Gd₂O₃, Ce₂O₃, CsI, BaFBr, CaWO₄ and BaO.

It is another advantage of the present invention that the range of metal elements which can be used for the x-ray absorbing layer, is much larger than the corresponding range of the pure metals and/or alloys, since many of them are not stable in their elemental form. Examples are the alkali metals, the alkaline earth metals and the rare-earth metals.

The chemical compounds having a metal element with an atomic number of 20 or more and one or more non-metal elements may be used in the X-ray absorbing layer of the present invention as powder dispersed in a binder. The amount of the binder in the X-ray absorbing layer in weight percent can vary in the range from 1% to 50%, preferably from 1% to 25%, more preferably from 1% to 10%, most preferably from 1% to 3%.

Suitable binders are e.g. organic polymers or inorganic binding components. Examples of suitable organic polymers are polyethylene glycol acrylate, acrylic acid, butenoic acid, propenoic acid, urethane acrylate, hexanediol diacrylate, copolyester tetracrylate, methylated melamine, ethyl acetate, methyl methacrylate. Inorganic binding components may be used as well. Examples of suitable inorganic binding components are alumina, silica or alumina nanoparticles, aluminium phosphate, sodium borate, barium phosphate, phosphoric acid, barium nitrate.

Preferred binders are organic polymers such as cellulose acetate butyrate, polyalkyl (meth)acrylates, polyvinyl-n-butyral, poly(vinylacetate-co-vinylchloride), poly(acrylonitrile-co-butadiene-co-styrene), poly(vinyl chloride-co-vinyl acetate-co-vinylalcohol), poly(butyl acrylate), poly(ethyl acrylate), poly(methacrylic acid), poly(vinyl butyral), trimellitic acid, butenedioic anhydride, phtalic anhydride, polyisoprene and/or a mixture thereof. Preferably, the binder comprises one or more styrene-hydrogenated diene block copolymers, having a saturated rubber block from polybutadiene or polyisoprene, as rubbery and/or elastomeric polymers. Particularly suitable thermoplastic rubbers, which can be used as block-copolymeric binders, in accordance with this invention, are the KRATON™ G rubbers, KRATON™ being a trade name from SHELL.

In case the coating of the X-ray absorbing layer is to be cured, the binder includes preferably a polymerisable compound which can be a monofunctional or polyfunctional monomer, oligomer or polymer or a combination thereof. The polymerisable compounds may comprise one or more polymerisable groups, preferably radically polymerisable groups. Any polymerisable mono- or oligofunctional monomer or oligomer commonly known in the art may be employed. Preferred monofunctional monomers are described in EP1637322A paragraph [0054] to [0057]. Preferred oligofunctional monomers or oligomers are described in EP1637322A paragraphs [0059] to [0064]. Particularly preferred polymerisable compound are urethane (meth)acrylates and 1,6-hexanedioldiacrylate. The urethane (meth)acrylates are oligomer which may have one, two, three or more polymerisable groups.

Suitable solvents, to dissolve the binder being an organic polymer during the preparation of the coating solution of the X-ray absorbing layer can be acetone, hexane, methyl acetate, ethyl acetate, isopropanol, methoxy propanol, isobutyl acetate, ethanol, methanol, methylene chloride and water. The most preferable ones are toluene, methyl-ethyl-ketone (MEK) and methyl cyclohexane. To dissolve suitable inorganic binding components, water is preferable as the main solvent. In case of a curable coating liquid, one or more mono and/or difunctional monomers and/or oligomers can be used as diluents. Preferred monomers and/or oligomers acting as diluents are miscible with the above described urethane (meth)acrylate oligomers. The monomer(s) or oligomer(s) used as diluents are preferably low viscosity acrylate monomer(s).

The X-ray absorbing layer of the present invention may also comprise additional compounds such as dispersants, plasticizers, photoinitiators, photocurable monomers, antistatic agents, surfactants, stabilizers oxidizing agents, adhesive agents, blocking agents and/or elastomers.

Dispersants which can be used in the present invention include non-surface active polymers or surface-active substances such as surfactants, added to the binder to improve the separation of the particles of the chemical compound having a metal element with an atomic number of 20 or more and one or more non-metal elements and to further prevent settling or clumping in the coating solution. Suitable examples of dispersants are Stann JF95B from Sakyo and Disperse Ayd™ 1900 from Daniel Produkts Company. The addition of dispersants to the coating solution of the X-ray absorbing layer improves further the homogeneity of the layer.

Suitable examples of plasticizers are Plastilit™ 3060 from BASF, Santicizer™ 278 from Solutia Europe and Palatinol™ C from BASF. The presence of plasticizers to the X-ray absorbing layer improves the compatibility with flexible substrates.

Suitable photo-initiators are disclosed in e.g. J.V. Crivello et al. in “Photoinitiators for Free Radical, Cationic & Anionic Photopolymerisation 2nd edition”, Volume III of the Wiley/SITA Series In Surface Coatings Technology, edited by G. Bradley and published in 1998 by John Wiley and Sons Ltd London, pages 276 to 294.Examples of suitable photoinitiators can be Darocure™ 1173 and Nuvopol™ PI-3000 from Rahn. Examples of suitable antistatic agents can be Cyastat™ SN50 from Acris and Lanco™ STAT K 100N from Langer.

Examples of suitable surfactants can be Dow CorningTM 190 and Gafac RM710, Rhodafac™ RS-710 from Rodia. Examples of suitable stabilizer compounds can be Brij™ 72 from ICI Surfactants and Barostab™ MS from Baerlocher Italia. An example of a suitable oxidizing agent can be lead (IV) oxide from Riedel De Haen. Examples of suitable adhesive agents can be CraynorTM 435 from Cray Valley and Lanco™ wax TF1780 from Noveon. An example of a suitable blocking agent can be Trixene™ BI7951 from Baxenden. An example of a suitable elastomer compound can be Metaline™ from Schramm).

The thickness of the X-ray absorbing layer, the atomic number of the metal element and the concentration of the chemical compound having a metal element with an atomic number of 20 or more can be chosen to achieve a desired level of X-ray absorption or attenuation in the RFPD. The value of this level can be expressed as the “absorption exponent” (AE) and should be equal to or higher than 0.5 to protect sufficiently the underlying electronics of the RFPD and to limit the impact from backscattered X-rays on the obtained image. The absorption exponent is a physical parameter that is equal to the negative of the natural logarithm of the X-ray transmittance. Since transmittance varies with X-ray energy, the absorption exponent is more conveniently expressed relative to X-rays emitted by a standard radiation source. A convenient standard is the 59.57 keV (hereafter 60 keV) gamma ray emission of Am²⁴¹. This source is in the middle range of X-ray energies typically used in medical imaging, 20 to 150 keV, and is commonly used as a source of monoenergetic X-rays for experiments. The absorption exponent can be measured directly or can be calculated using formula 1 (expressed here for a 60 keV gamma ray emission Am²⁴¹ source):

AE(Am²⁴¹ 60 keV)=t*(k₁e₁+k₂e₂+k₃e₃+ . . . ) (Formula 1)

wherein AE(Am²⁴¹ 60 keV) represents the absorption exponent of the substrate relative to the about 60 keV gamma ray emission of Am²⁴¹; t represents the thickness of the X-ray absorbing layer in the principle direction of propagation of the primary X-ray beam; e₁, e₂, e₃, . . . represent the concentrations of the elements in the X-ray absorbing layer; and k₁, k₂, k₃ . . . represent the mass attenuation coefficients of the respective elements at given energy. As the formula indicates, the absorption exponent is equal to a thickness dimension multiplied by the sum of the products of the mass attenuation coefficient for each element in the X-ray absorbing layer at the about 60 keV gamma ray emission of Am²⁴¹ and the respective concentration of each element in the X-ray absorbing layer. The absorption exponent is dimensionless. For example, if the mass attenuation coefficients are expressed in cm²/mole, the concentrations should be expressed in moles/cm³ and the thickness in centimetres. Mass attenuation coefficients can be found on the ‘National Institute for Standards and Technology’ (www.nist.gov/pml/data/xraycoef/). Depending on the application, the coating weight of the chemical compound having a metal element with an atomic number of 20 or more and one or more non metal elements in the X-ray absorbing layer can be flexibly adjusted and in case of using a RFPD for medical purposes, this coating weight is preferably at least 100 mg/cm², more preferably at least 200 mg/cm².

The thickness of the X-ray absorbing layer can vary as well and depends on the necessary shielding power and/or the space available to incorporate the X-ray shield in the design of the RFPD. In the present invention, the thickness of the X-ray absorbing layer can be at least 0.1 mm, more preferably in the range from 0.1 mm to 2.0 mm.

### The Light Absorbing or Light Reflecting Layer

Some of the chemical compounds having a metal element with an atomic number of 20 or more and at least one non-metal elements are scintillating phosphors which can emit light on X-ray absorption. If this is the case, light emitted by these scintillating phosphors in the X-ray absorbing layer can reach the imaging array through the substrate and contribute to the image formation. Due to scattering in the substrate of the imaging array of the light emitted by the scintillating phosphor present in the X-ray absorbing layer, the quality of the image of the investigated object is negatively impacted. In the case that scintillating phosphors are present in the X-ray absorbing layer, a light reflecting or light absorbing layer is to be present between the X-ray absorbing layer and the imaging array, more preferably between the X-ray absorbing layer and the substrate of the imaging array. In order to avoid any contribution of the emitted light by scintillating phosphors in the X-ray absorbing layer to the image, the transmission of the emitted light from the scintillating phosphor through this light absorbing or reflecting layer, should be equal to or lower than 10%, more preferable lower than 3%, most preferably lower than 1%. The term ‘scintillating phosphor’ in the X-ray absorbing layer according to the invention should be interpreted as a compound whose light emission on X-ray absorption can reach the imaging array and contribute to the image formation of the detector.

White coloured layers may be used to reflect light emitted by the scintillating phosphor in the X-ray absorbing layer. Layers comprising TiO₂ are preferably used to reflect 90% or more light at the wavelength(s) of the light emitted by the scintillating phosphor. The solid content of TiO₂ in the light reflecting layer is preferably in the range of 25 to 50 (wt.)%. and the thickness is preferably in the range of 5 to 40 μm. More preferably, the solid content of the TiO₂ is 33 to 38(wt.)% of the total solid content of the layer and the layer thickness is betweenl3 and 30 μm. The layer is preferably applied with a doctor blade coater on the substrate of the imaging array, preferably on the side opposite to the imaging array.

In another preferred embodiment of the invention, black coloured layers can be used to absorb light emitted by a scintillating phosphor in the X-ray absorbing layer because of their high efficiency to absorb light. Black particles, such as fine carbon black powder (ivory black, titanium black, iron black), are suitable to obtain sufficient absorption of emitted light by the scintillating phosphor. Preferably the solid content of carbon black is in the range of 3 to 30 (wt.)% and a layer thickness of 2 to 30 μm will absorb 90% or more of the emitted light by the scintillating phosphor. More preferably the range of the solid content of the carbon black is in the range of 6 to 15 (wt.)% and the layer thickness between 5 and15 μm. In another preferred embodiment of the invention, coloured pigments or dyes absorbing specifically at the maximal wavelength of the emitted light by the scintillating phosphor in the X-ray absorbing layer can be used.

### The Scintillator

In the RFPD for indirect conversion direct radiography according to the present invention, the scintillator comprises optionally a support and provided thereon, a scintillating phosphor such as one or more of Gd₂O₂S:Tb, Gd₂O₂S:Eu, Gd₂)₃:Eu, La₂O₂S:Tb, La₂O₂S, Y₂O₂S:Tb, CsI:Tl, CsI:Eu, CsI:Na, CsBr:Tl, NaI:Tl, CaWO₄, CaWO₄:Tb, BaFBr:Eu, BaFCI:Eu, BaSO₄:Eu, BaSrSO₄, BaPbSO₄, BaAI₁₂O₁₉:Mn, BaMgA₁₀O₁₇:Eu, Zn₂SiO₄:Mn, (Zn, Cd)S:Ag, LaOBr, LaOBr:Tm, Lu₂O₂S:Eu, Lu₂O₂S:Tb, LuTa0₄, HfO₂:Ti, HfGe0₄:Ti, YTa0₄, YTa0₄:Gd, YTa0₄:Nb, Y₂O₃:Eu, YBO₃:Eu, YBO₃:Tb, or (Y,Gd)BO₃:Eu, or combinations thereof. Besides crystalline scintillating phosphors, scintillating glass or organic scintillators can also be used.

When evaporated under appropriate conditions, a layer of doped CsI will condense in the form of needle like, closely packed crystallites with high packing density onto a support. Such a columnar or needle-like scintillating phosphor is known in the art. See, for example, ALN Stevels et al. , “Vapor Deposited CsI:Na Layers: Screens for Application in X-Ray Imaging Devices, ” Philips Research Reports 29:353-362 (1974); and T. Jing et al, “Enhanced Columnar Structure in CsI Layer by Substrate Patterning”, IEEE Trans. Nucl. Sci. 39: 1195-1198 (1992). More preferably, the scintillating phosphor layer includes doped CsI.

A blend of different scintillating phosphors can also be used. The median particle size is generally between about 0. 5 μm and about 40 μm. A median particle size of between 1 μm and about 20 μm is preferred for ease of formulation, as well as optimizing properties, such as speed, sharpness and noise. The scintillator for the preferred embodiments of the present invention can be prepared using conventional coating techniques whereby the scintillating phosphor powder, for example Gd₂O₂S is mixed with a solution of a binder material and coated by means of a blade coater onto a substrate. The binder can be chosen from a variety of known organic polymers that are transparent to X-rays, stimulating, and emitting light. Binders commonly employed in the art include sodium o-sulfobenzaldehyde acetal of poly(vinyl alcohol); chloro-sulfonated poly(ethylene); a mixture of macromolecular bisphenol poly(carbonates) and copolymers comprising bisphenol carbonates and poly(alkylene oxides);aqueous ethanol soluble nylons; poly(alkyl acrylates and methacrylates) and copolymers of poly(alkyl acrylates and methacrylates with acrylic and methacrylic acid); poly(vinyl butyral); and poly(urethane) elastomers. Other preferable binders which can be used are described above in the section of the X-ray absorbing layer. Any conventional ratio phosphor to binder can be employed. Generally, the thinner scintillating phosphor layers are, the sharper images are realized when a high weight ratio of phosphor to binder is employed. Phosphor-to-binder ratios in the range of about 70:30 to 99:1 by weight are preferable.

### The Photoconductive Layer

In the RFPD for direct conversion direct radiography, the photoconductive layer is usually amorphous selenium, although other photoconductors such as HgI₂, PbO, PbI₂, TlBr, CdTe and gadolinium compounds can be used. The photoconductive layer is preferentially deposited on the imaging array via vapour deposition but can also been coated using any suitable coating method.

### The Imaging Array and Its Substrate

The single imaging array for indirect conversion direct radiography is based on an indirect conversion process which uses several physical components to convert X-rays into light that is subsequently converted into electrical charges. First component is a scintillating phosphor which converts X-rays into light (photons). Light is further guided towards an amorphous silicon photodiode layer which converts light into electrons and electrical charges are created. The charges are collected and stored by the storage capacitors. A thin-film transistor (TFT) array adjacent to amorphous silicon read out the electrical charges and an image is created. Examples of suitable image arrays are disclosed in U.S. Pat. No. 5,262,649 and by Samei E. et al., “General guidelines for purchasing and acceptance testing of PACS equipment”, Radiographics, 24, 313-334. Preferably, the imaging arrays as described in US2013/0048866, paragraph [90-125] and US2013/221230, paragraphs [53-71] and [81-104] can be used.

The imaging array for direct conversion direct radiography is based on a direct conversion process of X-ray photons into electric charges. In this array, an electric field is created between a top electrode, situated on top of the photoconductor layer and the TFT elements. As X-rays strike the photoconductor, the electric charges are created and the electrical field causes to move them towards the TFT elements where they are collected and stored by storage capacitors. Examples of suitable image arrays are disclosed by Samei E. et al., “General guidelines for purchasing and acceptance testing of PACS equipment”, Radiographics, 24, 313-334.

For both the direct and indirect conversion process, the charges must be read out by readout electronics. Examples of readout electronics in which the electrical charges produced and stored are read out row by row, are disclosed by Samei E. et al., Advances in Digital Radiography. RSNA Categorical Course in Diagnostic Radiology Physics (p. 49-61) Oak Brook, Ill.

The substrate of the imaging array of the present invention is preferably glass. However, imaging arrays fabricated on substrates made of plastics, metal foils can also be used. The imaging array can be protected from humidity and environmental factors by a layer of silicon nitride or polymer based coatings such as fluoropolymers, polyimides, polyamides, polyurethanes and epoxy resins. Also polymers based on B-staged bisbenzocyclobutene-based (BCB) monomers can be used. Alternatively, porous inorganic dielectrics with low dielectric constants can also be used.

### The Underlying Electronics

The underlying electronics, situated under the X-ray absorbing layer comprise a circuit board which is equipped with electronic components for processing the electrical signal from the imaging array, and/or controlling the driver of the imaging array and is electrically connected to the imaging array.

### Method of Making the Radiographic Flat Panel Detector Method of Making the X-Ray Shield

The X-ray shield of the present invention can be obtained by applying an X-ray absorbing layer comprising at least one chemical compound having a metal element with an atomic number of 20 or more and one or more non-metal elements onto the substrate carrying the single imaging array. Preferably, the X-ray absorbing layer is applied on the side of the substrate opposite to the imaging array. Any known method for applying layers on a substrate can be suitable, e.g. Physical Vapour Deposition (PVD), Chemical Vapour Deposition (CVD), sputtering, doctor blade coating, spin-coating, dip-coating, spray-coating, knife coating, screen printing and lamination. The most preferable methods are doctor blade coating and PVD.

One of the preferred methods of applying a layer is by coating a solution, hereafter denoted as coating solution, comprising the chemical compound having a metal element with an atomic number of 20 or more and one or more non-metal elements and a binder onto the substrate of the single imaging array. In a preferred embodiment the coating solution is prepared by first dissolving the binder in a suitable solvent. To this solution the chemical compound having a metal element with an atomic number of 20 or more and one or more non-metal elements is added. To obtain a homogenous coating solution, a homogenization step or milling step of the mixture can be included in the preparation process. A dispersant can be added to the binder solution prior to the mixing with the chemical compound having a metal element with an atomic number of 20 or more and one or more non-metal elements. The dispersant improves the separation of the particles in the coating solution and prevents settling or clumping of the ingredients in the coating solution. The addition of dispersants to the coating solution of the X-ray absorbing layer further decreases the surface tension of the coating solution and improves the coating quality of the X-ray absorbing layer.

In another preferred embodiment of the invention, the binder being a polymerisable compound can be dissolved in diluents comprising one or more mono and/or difunctional monomers and/or oligomers.

After stirring or homogenization the coating solution is applied onto the substrate preferably using a coating knife or a doctor blade. By adjusting the distance between the coating blade and the substrate. After the coating of the X-ray absorbing layer, this layer can be dried via an IR-source, an UV-source, a heated metal roller or heated air. When photocurable monomers are used in the coating solution, the coated layer can be cured via heating or via an UV-source.

In another preferred embodiment, a PVD process is used in which the X-ray absorbing layer comprising the chemical compound having a metal element with an atomic number of 20 or more and one or more non-metal elements is prepared in vacuum from the gas phase of melting materials. The material in a solid form can be introduced in a heat resistive container to a vacuum chamber and subsequently heated to the temperature equal to or higher than the melting point of compound(s). The melted material vaporizes and condenses onto the substrate of the imaging array to form the X-ray absorbing layer. Metal compounds as salts, halides, sulphides and sulphates can be suitable in the PVD process due to their lower melting point. The X-ray absorbing layer is than a deposited crystalline film of chemical compound(s) having a metal element with an atomic number of 20 or more and one or more non-metal elements and is binder-less.

It is an advantage of the present method of the invention that the X-ray absorbing layer acting as an X-ray shield is directly applied on the substrate of the imaging array. Hence, a step wherein the X-ray shield has to be fixed to the substrate of the imaging array in the production, is avoided.

In another preferred embodiment, the X-ray absorbing layer can be applied on any functional layer which was directly applied or coated on the substrate of the imaging array prior to the application of the X-ray absorbing layer. Examples of functional layers are: light absorbing layer, reflecting layer, adhesion improving layer, protective layer, etc. Especially if the X-ray absorbing layer comprises a scintillating phosphor, a layer is present between the X-ray absorbing layer and the substrate, which has a transmission for light of 10% or lower at the wavelength of the light emission of the scintillating phosphor. This light absorbing or light reflecting layer can be coated on the substrate of the imaging array using conventional coating techniques known in the art.

### Method of Making the RFPD for Indirect Conversion Direct Radiography

The RFPD for indirect conversion direct radiography is made by assembling the different components which are described above. A preferred method is now described.

After applying the X-ray absorbing layer on the substrate of the single imaging array, the scintillator, which comprises a scintillating phosphor and optionally a support, is coupled via gluing onto the imaging array. Gluing is done with pressure sensitive adhesives or hot melts. Preferably a hot melt is used. Suitable examples of hot melts are polyethylene-vinyl acetate, polyolefins, polyamides, polyesters, polyurethanes, styrene block copolymers, polycarbonates, fluoropolymers, silicone rubbers, polypyrrole. The most preferred ones are polyolefins and polyurethanes due to the higher temperature resistance and stability. The hot melt is preferably thinner than 25 μm. The hot melt with a lining is placed onto the surface of the imaging array. The imaging array on its substrate, together with the hot melt is then heated in an oven at a prescribed temperature. After cooling, the lining is removed and releases a melted hot melt with a free adhesive side. The scintillator is coupled to the imaging array by bringing the scintillating phosphor layer in contact with the adhesive side of the hot melt and by applying a high pressure at a high temperature. To achieve a good sticking over the complete area of the imaging array, a pressure in a range from 0.6 to 20 bars has to be applied and a temperature value in a range from 80-220° C., during between 10 and 1000 s is required. A stack of scintillator-imaging array-substrate-X-ray absorbing layer is thereby formed.

In one preferred embodiment of the invention, this stack can be positioned above the underlying electronics which perform the processing of the electrical signal from the imaging array, or the controlling of the driver of the imaging array.

In a preferred embodiment of the invention, the scintillator phosphor of the scintillator is directly applied on the single imaging array via a coating or deposition process. This method has the advantage that no gluing is required and hence omits at least one step in the production process of the RFPD. Another advantage of the direct application of the scintillating phosphor on the imaging array, is the improved image quality.

In another preferred embodiment of the invention, the X-ray absorbing layer is applied to the substrate carrying the single imaging array, after the scintillator has been coupled to the imaging array according to the methods described above.

### Method of Making the RFPD for Direct Conversion Direct Radiography

The FPD for direct conversion direct radiography is made by assembling the different components which are described above.

A preferred method is as follows: after applying the X-ray absorbing layer to the substrate carrying the imaging array according to the same methods as described for making the X-ray shield, the photoconductor, preferably amorphous selenium is deposited onto the imaging array. Examples of deposition methods are disclosed in Fischbach et al., ‘Comparison of indirect CsI/a:Si and direct a:Se digital radiography’, Acta Radiologica 44 (2003) 616-621. A top electrode on top of the photoconductive layer is finally provided.

### EXAMPLES

### 1. Method of Measurement of the X-Ray Absorption

### 1.1. X-Ray Absorption Measurement of the X-Ray Shields

The combination of the X-ray absorbing layer, the substrate and the imaging array is denoted hereafter as X-ray shield. The X-ray absorption of the X-ray shields was measured with a Philips Optimus 80 apparatus together with Triad dosimeter having a 30 cc volume cell. The X-ray shield was placed with the imaging array directed towards the X-ray source. The measuring cell was placed at 1.5 m distance from the X-ray source directly behind the X-ray absorbing layer. All tests were done for standard radiation X-ray beam qualities (RQA5 X-ray beam qualities as defined in IEC standard 61267, 1^{st} Ed. (1994)): RQA5 (21 mm Al, 73 kV).

### 1.2. X-Ray Absorption Measurement of the RFPD

RFPDs were produced by applying Gd₂O₂S or CsI scintillating phosphors on the front side of the imaging array with its substrate having an X-ray absorbing layer at the opposite side of the imaging array. The RFPD was placed inside an in house-made frame, made of aluminium having a thickness of 500 μm. The X-ray absorption of the RFPD was measured with a Philips Optimus 80 apparatus together with Triad dosimeter having a 30 cc volume cell. The RFPD was placed with the scintillator directed towards the X-ray source. The measuring cell was placed at 1.5 m distance from the X-ray source directly behind the X-ray absorbing layer. Data for each RFPD were collected multiple times and the average value was calculated together with the standard deviation.

All tests were done for standard radiation X-ray beam qualities (RQA X-ray beam qualities as defined in IEC standard 61267, 1^{st} Ed. (1994)): RQA5 (21 mm Al, 73 kV) and RQA9 (40 mm Al, 117 kV).

### 2. Materials

Most materials used in the following examples were readily available from standard sources such as ALDRICH CHEMICAL Co. (Belgium), ACROS (Belgium) and BASF (Belgium) unless otherwise specified. All materials were used without further purification unless otherwise specified.

Gadolinium oxysulphide (Gd₂O₂S) or GOS: (CAS 12339-07-0) powder was obtained from Nichia, mean particle size: 3.3 μm;

Caesium iodide (CsI): (CAS 7789-17-5) from Rockwood Lithium, 99.999%.

ThI: Thallium iodide (CAS 62140-21-0) from Rockwood Lithium.

Disperse Ayd^{™} 9100 (Disperse Ayd^{™} W-22), anionic surfactant/Fatty Ester dispersant (from Daniel Produkts Company).

Kraton^{™} FG1901X (new name=Kraton^{™} FG1901 GT), a clear, linear triblock copolymer based on styrene and ethylene/butylene with a polystyrene content of 30%, from Shell Chemicals.

Imaging array: TFT (according U52013/0048866, paragraph [90-125] and U52013/221230, paragraphs [53-71] and [81-104]) on Corning Lotus™ Glass substrate having a thickness of 0.7 mm and a size of 18 cm×24 cm.

Aluminium having a thickness of 0.5 mm was obtained from Alanod.

TiO₂ R900:Ti-Pure® R-900 Titanium Dioxide from DuPont.

Filter AU09E11NG with pore size of 20 μm from 3M.

CAB 381-2: 20(wt.)% solution of Cellulose Acetate Butyrate (CAB-381-2) from Eastman in MEK. Prepared by stirring for 8 hours at 1600 rpm and filtering with Filter AU09E11NG after stirring.

Baysilone: Baysilone Paint additive MA from Bayer.

Ebecryl: 20(wt.)% solution of Ebecryl 1290, a hexafunctional aliphatic urethane acrylate oligomer from Allnex in MEK, prepared by stirring for 8 hours at 1600 rpm and filtering with Filter AU09E11NG after stirring.

Carbon black: Carbon black FW200 from Degussa

### 3. Preparation of X-Ray Shields

### 3.1. Preparation of the Solution for the Coating of the X-Ray Absorbing Layer

4.5 g of binder (Kraton^{™} FG1901X) was dissolved in 18 g of a solvent mixture of toluene and MEK (ratio 75:25 (wt.)) and stirred for 15 min at a rate of 1900 r.p.m. The GOS was added thereafter in an amount of 200 g and the mixture was stirred for another 30 minutes at a rate of 1900 r.p.m. The obtained GOS: binder ratio is 97.8:2.2 (wt).

### 3.2. Preparation of the Solution for the Light Reflecting Layer

0.2 g of CAB 381-2 was mixed with 1 g of TiO₂ R900, 0.001 g of Baysilone and 2.6 g of MEK in a horizontal agitator bead mill. Finally Ebecryl was added to achieve a CAB 381-2: Ebecryl ratio of 1:1 (wt.). The solution was filtered with Filter AU09E11NG. The solid content of TiO₂ R900 is of 35(wt.)%.

### 3.3. Preparation of the Solution for the Light Absorbing Layer

0.094 g of the 20 (wt.)% solution of CAB 381-2 in MEK as obtained in §3.2., was mixed with 0.126 g of Carbon black, 0.001 g of Baysilone, 0.094 g of Ebecryl, and 3.686 g of MEK in a pearl mill (pearls: YTZ 0.8 mm diameter) for at least 30 min. The solid content of the Carbon black obtained is 7.9 (wt.)%.

3.4. Preparation of X-Ray Shields SD-01 to SD-04 (INV) with GOS:

First the light reflecting layer was coated. The coating solution as obtained in §3.2. was coated with a doctor blade at a coating speed of 1.4 cm/s onto the glass substrate of the imaging array on the side opposite to the imaging array. The wet layer thickness was 250 μm as to obtain a dry layer thickness of 29 μm. The drying of the light reflecting layer was done at room temperature for at least 15 min. The transmission was measured at a wavelength 550 nm which correspond to the wavelength of the emitted light by the scintillating phosphor GOS. The transmission value at 550 nm amounts to 5.2%.

The coating solution as obtained in §3.1. was then coated with a doctor blade at a coating speed of 4 m/min onto the previously coated light reflecting layer. Different dry layer thicknesses variable from 100 to 450 μm were obtained by adjusting the distance between the coating blade and the substrate. Subsequently, the X-ray absorbing layer was dried at room temperature during 30 minutes. In order to remove volatile solvents as much as possible the coated X-ray shields were dried at 60° C. for 30 minutes and again at 90° C. for 20 to 30 minutes in a drying oven. The total thickness of the X-ray absorbing layer was controlled by adjusting the wet layer thickness and/or the number of layers coated on top of each other after drying each layer. The wet layer thickness has a value between 220 μm and 1500 μm.

After coating, each imaging array with the X-ray shield was weighed and the coating weight of the chemical compound having a metal element with an atomic number of 20 or more and one or more non metal elements in the X-ray absorbing layer was obtained by applying formula 2. The results are reported in Table 1

$$\frac{( {W}_{F} - {W}_{S} )}{{A}_{S}} * P \% \qquad Formula 2$$

### Where:

W_{F} is the weight of the imaging array+substrate+X-ray absorbing layer,

W_{S} is the weight of the imaging array+substrate,

A_{S} is the surface area of the substrate,

P % is the amount in weight % of the chemical compound having a metal element with an atomic number of 20 or more and one or more non-metal elements in the X-ray absorbing layer.

3.5. Preparation of X-Ray Shield SD-05 (INV) with Caesium Iodide (CsI):

SD-05 was prepared via physical vapour deposition of CsI on the substrate of the imaging array. 400 g of CsI was placed in a container in a vacuum deposition chamber. The pressure in the chamber was decreased to 5.10⁻⁵ mbar. The container was subsequently heated to a temperature of 680° C. and the CsI was deposited on the glass substrate on the side opposite to the imaging array. The CsI-layer as obtained did not show a substantial scintillating effect and hence can not be considered as a phosphor scintillator. Indeed, only a very low light emission is observed below 400 nm which is in a wavelength range where the imaging array is not sensitive enough to contribute to the image of the investigated object. The X-ray absorbing layer of CsI as obtained does not comprise a scintillating phosphor and hence no light absorbing or light reflecting layer was present between the substrate of the imaging array and the X-ray absorbing layer comprising the CsI. The distance between the container and the substrate was 20 cm.

During evaporation, the substrate was rotated at 12 r.p.m. and kept at elevated temperature of 140° C. During the evaporation process argon gas was introduced into the chamber. The duration of the process is 160 min. After the deposition, the imaging array with its substrate and the X-ray shield was weighed and the coating weight was obtained by applying formula 2 where P % is 100. The result is reported in Table 1.

### 3.6. Molybdenum X-Ray Shield (COMP)

An X-ray shield based on a plate of Molybdenum (Mo) was obtained from one of the commercially available RFPDs on the market. The thickness of the Molybdenum plate was 0.3 mm. The Molybdenum plate did not contain a substrate. The composition of the plate was 99.85% (wt.) of Mo, and below 0.05% (wt.) of Na, K, Ca, Ni, Cu, and Bi.

The coating weight for this Mo plate was calculated based on formula 2 taking into account that WF is the weight of the plate, P % is 100 and Ws is 0. The results of the calculated coating weight of the Mo plate, were reported in Table 1.

TABLE 1
Table 1: Coating weights and absorption exponent (AE)
of the GOS or CsI in the inventive X-ray shields (SD-01
to SD-05) and of the comparative Mo plate.

| | Compound having a | Thickness | | |
|---|---|---|---|---|
| | metal element with an | of the X- | | |
| | atomic number ≧20 | ray | | |
| | and ≧1 non-metal | absorbing | Coating | Absorption |
| X-ray | elements in the X-ray | layer | weight | exponent |
| shield | absorbing layer | (μm) | (mg/cm²) | (AE) |
| SD-01 | GOS | 325 | 172 | 0.79 |
| (INV) | | | | |
| SD-02 | GOS | 325 | 172 | 0.79 |
| (INV) | | | | |
| SD-03 | GOS | 230 | 115 | 0.56 |
| (INV) | | | | |
| SD-04 | GOS | 330 | 155 | 0.80 |
| (INV) | | | | |
| SD-05 | CsI | 300 | 112 | 0.56 |
| (INV) | | | | |
| Mo- | — | 300 | 302 | 0.97 |
| plate | | | | |

3.7. Preparation of X-Ray Shields with or Without Dispersant.

To illustrate the difference between GOS X-ray shields prepared with or without a dispersant in the coating solution of the X-ray absorbing layer, two X-ray shields based on GOS were prepared according to the method described in §3.1. Shield SD-01 was prepared without dispersant in the coating solution and SD-02 was prepared with dispersant added to the coating solution: 0.5 g of dispersant (Disperse Ayd™ 9100) was dissolved in 11.21 g of a toluene and methyl-ethyl-ketone (MEK) solvent mixture, having a ratio of 75:25 (wt) and mixed with the binder solution as prepared in §3.1. The further preparation steps are the same as described in §3.1 to §3.4. The coating weight of the GOS was for both X-ray shields equal to 172 mg/cm². The X-ray absorption of both shields was determined according §1.1. The results are shown in Table 2.

TABLE 2
Table 2: X-ray absorption of GOS X-ray shields
prepared with or without dispersant.

| | | | Thickness | | |
|---|---|---|---|---|---|
| | | | of X-ray | | X-ray |
| X-ray | | Coating | absorbing | Weight | absorption |
| shield | Dispersant | quality | layer (μm) | (g) | (%) |
| SD-01 | no | good | 325 | 152.15 | 63.3 ± 2.5 |
| (INV) | | | | | |
| SD-02 | yes | perfect | 325 | 152.50 | 63.6 ± 2.5 |
| (INV) | | | | | |

As shown in Table 2, the X-ray shield prepared with the dispersant present in the coating solution had a more homogeneous X-ray absorbing layer for a comparable weight and X-ray absorption as the X-ray shield prepared without dispersant. The presence of the dispersant is advantageous for the preparation process of the shields since it further reduces the surface tension and prevents the floating of μm size particles.

### 4. X-Ray Absorption of Inventive X-Ray Shields and Comparative Mo Shield Coupled to the Substrate of the Imaging Array

The X-ray absorption of the inventive X-ray shields SD-03, SD-05 and comparative shield SD-06 was measured according §1.1. The comparative X-ray shield SD-06 was obtained by contacting the Mo plate to the substrate of the imaging array at the opposite side of the imaging array. The results are shown in Table 3.

TABLE 3
Table 3: Properties of inventive and comparative X-ray shields.

| | | | | | Weight X- |
|---|---|---|---|---|---|
| | Thick- | Coating | | Absorption | ray |
| X-ray | ness | weight | Absorption | exponent | absorbing |
| shield | (μm) | (mg/cm²) | (%) | (AE) | layer (g) |
| SD-03 | 230 | 115 | 46.1 | 0.66 | 61.1 |
| (INV) | | | | | |
| SD-04 | 330 | 155 | 57.1 | 0.95 | 87.7 |
| (INV) | | | | | |
| SD-05 | 300 | 112 | 46.5 | 0.62 | 58.4 |
| (INV) | | | | | |
| SD-06 | 300 | 302 | 74.5 | 0.97 | 132.5 |
| (COMP) | | | | | |

Although the X-ray absorption of the inventive X-ray shields is lower than the X-ray absorption of the comparative X-ray shield, the weight of the inventive shields is considerably lower than the comparative X-ray shield. Indeed, to have an absorption exponent for X-ray energies in the middle range of X-ray energies typically used in medical imaging equal to X-ray shield SD-05, the thickness of the Mo plate should be 170 μm and hence weigh considerably higher than SD-05. Unfortunately, Mo-plates with a thickness of 170 μm are not available and could hence not be included in the example. The comparison of the two preferred compounds in the X-ray absorbing layer of the inventive X-ray shields showed no significant difference in the X-ray absorption capabilities.

### 5. Example 1

### 5.1. Preparation of RFPDs Comprising Different X-Ray Shields

RFPDs for indirect conversion direct radiography were prepared by bringing a scintillator in contact with the X-ray shields described in §3. To assure a good optical contact between scintillating phosphor layer and the imaging array, the scintillating phosphor was directly deposited or coated on the imaging array. The scintillating phosphors used are GOS or needle-based doped CsI. The GOS comprising scintillating phosphor layer was prepared as follows: 0.5 g of dispersant (Disperse Ayd™ 9100) was dissolved in 11.21 g of a toluene and methyl-ethyl-ketone (MEK) solvent mixture, having a ratio of 75:25 (w/w) and mixed with the binder solution as prepared in §3.1. The obtained coating solution was coated on the imaging array, the same way as §3.4. with a coating weight of 115 mg/cm². The needle-based doped CsI was prepared and deposited at a coating weight of 120 mg/cm² on the imaging array in the same way as described in §3.5. with additional 1 (wt.)% of thallium dopant. The doping with thallium was obtained by adding ThI to the CsI during the vapour deposition process. The comparative RFPD, DRGOS-06 was prepared as described above, but the X-ray absorbing layer on the substrate carrying the imaging array is replaced by a Mo plate which was brought in contact to the substrate of the imaging array at the opposite side of the imaging array. The obtained RFPDs are summarised in Table 4.

TABLE 4
Table 4: RFPDs based on different scintillators and X-ray shields.

| RFPD | Scintillator | X-ray shield |
|---|---|---|
| DRGOS-01(INV) | GOS | SD-01 |
| DRGOS-02(INV) | GOS | SD-02 |
| DRGOS-03(INV) | GOS | SD-03 |
| DRGOS-04(INV) | GOS | SD-04 |
| DRGOS-05(INV) | GOS | SD-05 |
| DRCSI-01(INV) | CsI | SD-01 |
| DRCSI-02(INV) | CsI | SD-02 |
| DRCSI-03(INV) | CsI | SD-03 |
| DRCSI-04(INV) | CsI | SD-04 |
| DRCSI-05(INV) | CsI | SD-05 |
| DRGOS-06 (COMP) | GOS | Mo |
| DRCSI-06 (COMP) | CsI | Mo |

### 5.1. X-Ray Absorption of Inventive and Comparative RFPDs.

The X-ray absorption of inventive RFPDs (DRGOS-03 and DRGOS-04) and a comparative RFPD (DRGOS-06) was measured according to §1.2. with following X-ray beam qualities and loads: RQA5-6.3 mAs and RQA9-3 mAs. The results of the measurements are provided in Table 5.

TABLE 5
Table 5: X-ray absorption of inventive and comparative RFPDs.

| | % absorption of X- | % absorption of X- |
|---|---|---|
| | ray beam quality | ray beam quality |
| RFPD | RQA5 | RQA9 |
| DRGOS-03 (INV) | 43.2 | 34.8 |
| DRGOS-04 (INV) | 54.2 | 44.4 |
| DRGOS-06 (COMP) | 78.1 | 50.0 |

The inventive RFPDs (DRGOS-03 and DRGOS-04) showed lower absorption for X-ray beam quality RQA5 (6.3 mAs) in comparison with the comparative RFPD (DRGOS-06). With the X-ray beam quality RQA9 (3 mAs), the inventive RFPDs (DRGOS-03 and DRGOS-04) showed a comparable X-ray absorption as to the RFPD with the comparative Mo X-ray shield. The inventive RFPDs have, as additional advantage, a lower weight than the comparative one. The inventive RFPDs can also be produced on a more economically efficient way than the comparative one since the fixing or gluing step between the substrate of the imaging array and the X-ray absorbing layer is not required.

1-10. (canceled)

11. A radiography flat panel detector comprising, in order:
a scintillating layer or a photoconductive layer;
a single imaging array;
a substrate;
an X-ray absorbing layer including a chemical compound having a metal element with an atomic number of 20 or more and one or more non-metal elements; wherein
the X-ray absorbing layer has a dimensionless absorption exponent of greater than 0.5 for gamma ray emission of Am²⁴¹ at about 60 keV;
AE(Am²⁴¹ 60 keV)=t*(k₁e₁+k₂e₂+k₃e₃+ . . . );
AE(Am²⁴¹ 60 keV) represents the dimensionless absorption exponent of the X-ray absorbing layer relative to the about 60 keV gamma ray emission of Am²⁴¹;
t represents a thickness of the X-ray absorbing layer;
e₁, e₂, e₃, . . . represent concentrations of elements in the X-ray absorbing layer;
k₁, k₂, k₃ . . . represent mass attenuation coefficients of the elements, respectively, in the X-ray absorbing layer; and
if the chemical compound is a scintillating phosphor, a layer is present between the X-ray absorbing layer and the substratehas a transmission for light of 10% or lower at a wavelength of light emission of the chemical compound.

12. The radiography flat panel detector according to claim 11, wherein the X-ray absorbing layer is disposed between the substrate and underlying electronics.

13. The radiography flat panel detector according to claim 11, wherein the chemical compound is selected form the group consisting of CsI, Gd₂O₂S, BaFBr, CaWO₄, BaTiO₃, Gd₂O₃, BaCl₂, BaF₂, BaO, Ce₂O₃, CeO₂, CsNO₃, GdF₂, PdI₂, TeO₂, SnI₂, SnO, BaSO₄, BaCO₃, Bal, BaFX, RFXₙ, RF_{y}O_{z}, RF_{y}(SO₄)_{z}, RF_{y}S_{z}, RF_{y}(WO₄)_{z}, CsBr, CsCl, CsF, CsNO₃, Cs₂SO₄, Osmium halides, Osmium oxides, Osmium sulphides, Rhenium halides, Rhenium oxides, and Rhenium sulphides or mixtures thereof;
X is a halide selected from the group of F, CI, Br, and I;
RF is a lanthanide selected from La, Ce, Pr, Nd, Pm, Sm, Eu, Gd, Tb, Dy, Ho, Er, Tm, Yb, and Lu; and
n, y, and z are independently an integer number higher than 1.

14. The radiography flat panel detector according to claim 12, wherein the chemical compound is selected from the group consisting of CsI, Gd₂O₂S, BaFBr, CaWO₄, BaTiO₃, Gd₂O₃, BaCl₂, BaF₂, BaO, Ce₂O₃, CeO₂, CsNO₃, GdF₂, PdI₂, TeO₂, SnI₂, SnO, BaSO₄, BaCO₃, BaI, BaFX, RFXn, RF_{y}O_{z}, RF_{y}(SO₄)_{z}, RF_{y}S_{z}, RF_{y}(WO₄)_{z}, CsBr, CsCl, CsF, CsNO₃, Cs₂SO₄, Osmium halides, Osmium oxides, Osmium sulphides, Rhenium halides, Rhenium oxides, and Rhenium sulphides or mixtures thereof;
X is a halide selected from the group of F, CI, Br, and I;
RF is a lanthanide selected from La, Ce, Pr, Nd, Pm, Sm, Eu, Gd, Tb, Dy, Ho, Er, Tm, Yb, and Lu; and
n, y, and z are independently an integer number higher than 1.

15. The radiography flat panel detector according to claim 11, wherein the X-ray absorbing layer includes a binder.

16. The radiography flat panel detector according to claim 12, wherein the X-ray absorbing layer includes a binder.

17. The radiography flat panel detector according to claim 13, wherein the X-ray absorbing layer includes a binder.

18. The radiography flat panel detector according to claim 15, wherein an amount of the binder in the X-ray absorbing layer is 10% by weight or less.

19. The radiography flat panel detector according to claim 16, wherein an amount of the binder in the X-ray absorbing layer is 10% by weight or less.

20. The radiography flat panel detector according to claim 11, wherein the layer having the transmission for light of 10% or lower at the wavelength of the light emission of the chemical compound includes a dye or a pigment.

21. The radiography flat panel detector according to claim 12, wherein the layer having the transmission for light of 10% or lower at the wavelength of the light emission of the chemical compound includes a dye or a pigment.

22. The radiography flat panel detector according to claim 15, wherein the layer having the transmission for light of 10% or lower at the wavelength of the light emission of the chemical compound includes a dye or a pigment.

23. The radiography flat panel detector according to claim 18, wherein the layer having the transmission for light of 10% or lower at the wavelength of the light emission of the chemical compound includes a dye or a pigment.

24. The radiography flat panel detector according to claim 11, wherein the layer having the transmission for light of 10% or lower at the wavelength of the light emission of the chemical compound absorbs light.

25. The radiography flat panel detector according to claim 12, wherein the layer having the transmission for light of 10% or lower at the wavelength of the light emission of the chemical compound absorbs light.

26. The radiography flat panel detector according to claim 15, wherein the layer having the transmission for light of 10% or lower at the wavelength of the light emission of the chemical compound absorbs light.

27. The radiography flat panel detector according to claim 18, wherein the layer having the transmission for light of 10% or lower at the wavelength of the light emission of the chemical compound absorbs light.

28. The radiography flat panel detector according to claim 11, wherein the layer having the transmission for light of 10% or lower at the wavelength of the light emission of the chemical compound includes light reflecting particles.

29. The radiography flat panel detector according to claim 12, wherein the layer having the transmission for light of 10% or lower at the wavelength of the light emission of the chemical compound includes light reflecting particles.

30. The radiography flat panel detector according to claim 15, wherein the layer having a transmission for the light of 10% or lower at the wavelength of the light emission of the chemical compound includes light reflecting particles.

31. The radiography flat panel detector according to claim 18, wherein the layer having a transmission for the light of 10% or lower at the wavelength of the light emission of the chemical compound includes light reflecting particles.

32. A method of making the radiography flat panel detector as defined in claim 11, the method comprising the steps of:
providing the substrate with the imaging array on a side of the substrate;
applying a scintillating phosphor onto the imaging array; and
applying the X-ray absorbing layer on a side of the substrate opposite to the imaging array.

33. The method of making a radiography flat panel detector according to claim 32, wherein the step of applying the X-ray absorbing layer includes coating the X-ray absorbing layer using a knife or a doctor blade.
